(19) United States
(12) Patent Application Publication
(10) Pub. No.: US 2024/0043724 A1
(43) Pub. Date: Feb. 8, 2024

(54) PRESSURE-SENSITIVE ADHESIVE SHEET FOR SEMICONDUCTOR PROCESSING

(71) Applicant: NITTO DENKO CORPORATION, Osaka (JP)

(72) Inventors: Yuji KATO, Ibaraki-shi (JP); Jun AKIYAMA, Ibaraki-shi (JP); Taiki UENO, Ibaraki-shi (JP)

(21) Appl. No.: 18/358,853

(22) Filed: Jul. 25, 2023

(30) Foreign Application Priority Data
Jul. 26, 2022 (JP) 2022-119113

(51) Int. Cl. C09J 11/06; C09J 7/38; C09J 133/08; H01L 21/683

(52) U.S. Cl. CPC C09J 11/06; C09J 7/38; C09J 133/08; H01L 21/6836; C09J 2301/408; C09J 2301/302; C09J 2301/314; C09J 2433/00

(57) ABSTRACT

Provided is a pressure-sensitive adhesive sheet for semiconductor processing having excellent followability to unevenness of an adherend, and an excellent anchoring property. The pressure-sensitive adhesive sheet for semiconductor processing includes a pressure-sensitive adhesive layer formed of an ultra-violet (UV)-curable pressure-sensitive adhesive, and a base material. The UV-curable pressure-sensitive adhesive contains a base polymer, a photopolymerization initiator, and a phosphoric acid ester-based surfactant.

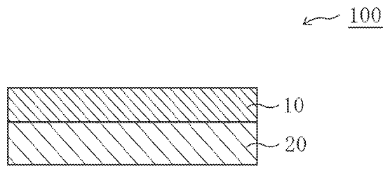

### CROSS REFERENCE TO RELATED APPLICATIONS

This application claims priority under 35 U.S.C. Section 119 to Japanese Patent Application No. 2022-119113 filed on Jul. 26, 2022, which is herein incorporated by reference.

### BACKGROUND OF THE INVENTION

### 1. Field of the Invention

The present disclosure relates to a pressure-sensitive adhesive sheet for semiconductor processing.

### 2. Description of the Related Art

A semiconductor wafer is used for various usages, such as a personal computer, a smartphone, and an automobile. In a processing process for the semiconductor wafer, a pressure-sensitive adhesive tape is used for protecting a surface thereof at the time of processing. In recent years, the miniaturization and high functionalization of a large-scale integration (LSI) have been proceeding, and a surface structure of a wafer has become complex. A specific example thereof is a complex three-dimensional structure of a wafer surface obtained by a solder bump, an electrode, or the like. Accordingly, the pressure-sensitive adhesive tape to be used in the semiconductor processing process is required to have followability to unevenness of the wafer surface. A pressure-sensitive adhesive having flexibility is used for a pressure-sensitive adhesive layer of a pressure-sensitive adhesive sheet having followability to unevenness. Such pressure-sensitive adhesive sheet has excellent followability to unevenness but has a problem in an anchoring force with a base material.

In recent years, along with the downsizing and thinning of products, the thinning of the semiconductor wafer has been advanced. In the wafer processed into a thin shape, when the pressure-sensitive adhesive strength of the pressure-sensitive adhesive tape is too high, the wafer may break at the time of the peeling of the pressure-sensitive adhesive tape. Accordingly, in order to prevent an adhesive residue on an adherend and breaking of the wafer at the time of the peeling of the tape, a pressure-sensitive adhesive tape using an ultra-violet (UV)-curable pressure-sensitive adhesive has been proposed (for example, Japanese Patent Application Laid-open No. 2020-017758 and Japanese Patent Application Laid-open No. 2013-213075). When the anchoring force between the base material and the pressure-sensitive adhesive layer is insufficient, there is a problem in that, when the pressure-sensitive adhesive tape is subjected to UV curing to be peeled, anchoring failure occurs, resulting in an adhesive residue on the adherend. To cope with such problems, there has been a proposal of forming an undercoating layer on a base material to improve the anchoring force of the pressure-sensitive adhesive layer to the base material. However, the number of production steps for the pressure-sensitive adhesive sheet increases, and hence a yield may reduce. In addition, the processing process for the semiconductor wafer may include a washing step with a solvent. When such step is included, the undercoating layer may be dissolved in the solvent, and hence an anchoring force-improving effect on the pressure-sensitive adhesive layer may not be sufficiently obtained.

### SUMMARY OF THE INVENTION

The present disclosure has been made to solve the above-mentioned problems of the related art, and an object of the present disclosure is to provide a pressure-sensitive adhesive sheet for semiconductor processing having excellent followability to unevenness and an excellent anchoring property.
1. In a first aspect according to at least one embodiment of the present disclosure, there is provided a pressure-sensitive adhesive sheet for semiconductor processing, including a pressure-sensitive adhesive layer formed of an ultra-violet (UV)-curable pressure-sensitive adhesive, and a base material. The UV-curable pressure-sensitive adhesive contains a base polymer, a photopolymerization initiator, and a phosphoric acid ester-based surfactant.
2. In the pressure-sensitive adhesive sheet for semiconductor processing according to the above-mentioned first aspect, the phosphoric acid ester-based surfactant may have a content of 0.03 part by weight or more with respect to 100 parts by weight of the base polymer.
3. In the pressure-sensitive adhesive sheet for semiconductor processing according to the above-mentioned first or second aspect, the pressure-sensitive adhesive layer may have an anchoring force after UV curing of 1 N/20 mm or more.
4. In the pressure-sensitive adhesive sheet for semiconductor processing according to any one of the above-mentioned first to third aspects, the UV-curable pressure-sensitive adhesive may further contain a cross-linking agent, and the cross-linking agent may have a content of 1 part by weight or less with respect to 100 parts by weight of the base polymer.
5. In the pressure-sensitive adhesive sheet for semiconductor processing according to the above-mentioned fourth aspect, the cross-linking agent may be an isocyanate-based cross-linking agent.
6. In the pressure-sensitive adhesive sheet for semiconductor processing according to any one of the above-mentioned first to fifth aspects, the base polymer may be a polymer having a carbon-carbon double bond.
7. In the pressure-sensitive adhesive sheet for semiconductor processing according to any one of the above-mentioned first to sixth aspects, the base material may contain a polyolefin-based resin.
8. The pressure-sensitive adhesive sheet for semiconductor processing according to any one of the above-mentioned first to seventh aspects may be used in a semiconductor processing process including a solvent washing step.

### BRIEF DESCRIPTION OF THE DRAWINGS

The FIGURE is a schematic sectional view of a pressure-sensitive adhesive sheet for semiconductor processing according to at least one embodiment of the present disclosure.

### DESCRIPTION OF THE EMBODIMENTS

A. Overall Configuration of Pressure-Sensitive Adhesive Sheet for Semiconductor Processing

The FIGURE is a schematic sectional view of a pressure-sensitive adhesive sheet for semiconductor processing according to at least one embodiment of the present disclosure. In the illustrated example, a pressure-sensitive adhesive sheet 100 for semiconductor processing includes a base material 10 and a pressure-sensitive adhesive layer 20 arranged on one surface of the base material. The pressure-sensitive adhesive sheet for semiconductor processing may include any appropriate other layer (not shown). For example, any appropriate layer (e.g., an intermediate layer) may be formed between the base material and the pressure-sensitive adhesive layer. The base material 10 is a single layer in the illustrated example, but may be a laminate of two or more layers. In the pressure-sensitive adhesive sheet for semiconductor processing, a release liner may be arranged outside the pressure-sensitive adhesive layer for the purpose of protecting the pressure-sensitive adhesive layer until the sheet is subjected to use.

The thickness of the pressure-sensitive adhesive sheet for semiconductor processing according to at least one embodiment of the present disclosure may be set to any appropriate thickness. The thickness of the pressure-sensitive adhesive sheet for semiconductor processing is, for example, preferably from 10 μm to 1,000 μm, more preferably from 50 μm to 300 μm, still more preferably from 100 μm to 300 μm.

B. Base Material

The base material may be formed of any appropriate resin. Specific examples of the resin for forming the base material include polyester-based resins, such as polyethylene terephthalate (PET), polyethylene naphthalate (PEN), polybutylene terephthalate (PBT), and polybutylene naphthalate (PBN), an ethylene-vinyl acetate copolymer, an ethylene-methyl methacrylate copolymer, polyolefin-based resins, such as polyethylene, polypropylene, and an ethylene-propylene copolymer, polyvinyl alcohol, polyvinylidene chloride, polyvinyl chloride, a vinyl chloride-vinyl acetate copolymer, polyvinyl acetate, polyamide, polyimide, celluloses, a fluorine-based resin, polyether, polystyrene-based resins such as polystyrene, polycarbonate, and polyether sulfone. Of those, polyester-based resins, such as polyethylene terephthalate (PET), polyethylene naphthalate (PEN), polybutylene terephthalate (PBT), and polybutylene naphthalate (PBN), and polyolefin-based resins, such as polyethylene, polypropylene, and an ethylene-propylene copolymer, are preferably used, and polyolefin-based resins are more preferably used. When these resins are used, followability to unevenness improves, and hence adhesiveness to an adherend having unevenness on its surface can be improved. The base material may be a single layer, or may be a laminate of two or more layers. When the base material is a laminate of two or more layers, it is preferred that the preferred resin be a resin for forming at least a layer in contact with the pressure-sensitive adhesive layer of the base material that is a laminate.

The base material may further include another component to the extent that the effects of the present disclosure are not inhibited. Examples of the other component include an antioxidant, an ultra-violet (UV) absorber, a light stabilizer, and a heat stabilizer. With regard to the kind and usage amount of the other component, the other component may be used in any appropriate amount in accordance with purposes.

The thickness of the base material is preferably from 10 μm to 200 μm, more preferably from 20 μm to 150 μm.

C. Pressure-Sensitive Adhesive Layer

The pressure-sensitive adhesive layer is formed of a UV-curable pressure-sensitive adhesive. The UV-curable pressure-sensitive adhesive typically contains a base polymer and a photopolymerization initiator. The pressure-sensitive adhesive layer formed of the UV-curable pressure-sensitive adhesive can provide a pressure-sensitive adhesive sheet having excellent pressure-sensitive adhesive strength to an adherend before the UV curing and excellent peelability after the UV curing. In the pressure-sensitive adhesive sheet for semiconductor processing according to at least one embodiment of the present disclosure, the UV-curable pressure-sensitive adhesive for forming the pressure-sensitive adhesive layer contains a phosphoric acid ester-based surfactant. The pressure-sensitive adhesive layer that is formed using such pressure-sensitive adhesive has an excellent anchoring property to the base material even when a soft (for example, low-cross-linking-degree) pressure-sensitive adhesive is adopted for improving unevenness followability. Accordingly, anchoring failure at an interface between the base material and the pressure-sensitive adhesive layer at the time of the peeling of the pressure-sensitive adhesive sheet after the UV curing is suppressed, and hence an adhesive residue on an adherend can be suppressed. In addition, even when the semiconductor processing process using the pressure-sensitive adhesive sheet for semiconductor processing includes a solvent washing step, the pressure-sensitive adhesive layer is suppressed from being dissolved in the solvent. Accordingly, the pressure-sensitive adhesive sheet can be also suitably used in a semiconductor processing process including a solvent washing step.

The modulus of elasticity of the pressure-sensitive adhesive layer before the UV curing is preferably from 0.05 MPa to 1.20 MPa, more preferably from 0.10 MPa to 1.00 MPa, still more preferably from 0.17 MPa to 0.95 MPa. When the modulus of elasticity of the pressure-sensitive adhesive layer before the UV curing falls within such ranges, the pressure-sensitive adhesive layer can follow the unevenness of an adherend, and hence a pressure-sensitive adhesive sheet for semiconductor processing having an excellent unevenness-embedding property can be provided. The modulus of elasticity of the pressure-sensitive adhesive layer may be measured with, for example, a nanoindenter.

The anchoring force of the pressure-sensitive adhesive layer after the UV curing is preferably 1 N/20 mm or more, more preferably from 1.5 N/20 mm to 10 N/20 mm, still more preferably from 2 N/20 mm to 8 N/20 mm. When the anchoring force after the UV curing falls within such ranges, the anchoring failure at the interface between the base material and the pressure-sensitive adhesive layer can be suppressed. The anchoring force herein refers to a peel force measured by the following method. (i) A pressure-sensitive adhesive sheet for semiconductor processing is cut out into a size of 20 mm wide by 150 mm long, and a stainless steel (SUS) plate is bonded to the entirety of the surface of the pressure-sensitive adhesive sheet opposite to its pressure-sensitive adhesive layer (e.g., in the case of a pressure-sensitive adhesive sheet having the configuration “base material/pressure-sensitive adhesive layer,” a surface of the base material on which the pressure-sensitive adhesive layer is not formed (outer surface)) via a predetermined double-sided tape. (ii) A pressure-sensitive adhesive surface of a sheet for pressure-sensitive adhesive property evaluation having a size of 20 mm wide by 150 mm long and containing a polyester-based resin (a sheet having a peeling pressure-sensitive adhesive strength of from 10 N/20 mm to 20 N/20 mm with respect to polyethylene terephthalate such as a product available under the product name: “No. 315 Tape” from Nitto Denko Corporation) is bonded to an outer surface (surface not in contact with the base material) of the pressure-sensitive adhesive layer of the pressure-sensitive adhesive sheet that has been cut out to provide an evaluation sample. (iii) A peel force between the base material and the pressure-sensitive adhesive layer of the evaluation sample is measured by a tensile test. The above-mentioned steps (i) to (iii) are each performed under an environmental temperature of 23° C. For the measurement of the peel force, the tensile test is performed under the conditions of a peel rate of 50 mm/min and a peel angle of 180°.

C-1. UV-Curable Pressure-Sensitive Adhesive

Any appropriate pressure-sensitive adhesive may be used as the UV-curable pressure-sensitive adhesive. For example, a pressure-sensitive adhesive obtained by adding a UV-curable monomer and/or oligomer to any appropriate pressure-sensitive adhesive, such as an acrylic pressure-sensitive adhesive, a rubber-based pressure-sensitive adhesive, a silicone-based pressure-sensitive adhesive, or a polyvinyl ether-based pressure-sensitive adhesive, may be adopted, or a pressure-sensitive adhesive using a polymer having a carbon-carbon double bond as a base polymer may be adopted. Of those, a pressure-sensitive adhesive containing a polymer having a carbon-carbon double bond as a base polymer is preferably used.

C-1-1. Base Polymer

The base polymer having a carbon-carbon double bond may have a carbon-carbon double bond in a main chain thereof, may have a carbon-carbon double bond in a side chain thereof, or may have a carbon-carbon double bond at a terminal thereof. When the base polymer having a carbon-carbon double bond is used, a polymer having a polymerizable carbon-carbon double bond and having a pressure-sensitive adhesive property is used as the base polymer. Examples of such polymer include polymers each obtained by introducing a carbon-carbon double bond into a resin, such as a (meth)acrylic resin, a vinyl alkyl ether-based resin, a silicone-based resin, a polyester-based resin, a polyamide-based resin, a urethane-based resin, or a styrene-diene block copolymer. Of those, a (meth)acrylic polymer obtained by introducing a carbon-carbon double bond into a (meth)acrylic resin is preferably used. When the (meth)acrylic polymer is used, a pressure-sensitive adhesive sheet in which the storage modulus of elasticity and tensile modulus of elasticity of the pressure-sensitive adhesive layer are easily adjusted, and which is excellent in balance between pressure-sensitive adhesive strength and peelability can be obtained. Further, contamination of an adherend by a component derived from the pressure-sensitive adhesive can be reduced. The “(meth)acrylic” refers to acrylic and/or methacrylic.

Any appropriate (meth)acrylic resin may be used as the (meth)acrylic resin. An example of the (meth)acrylic resin is a polymer obtained by polymerizing a monomer composition containing one kind or two or more kinds of esters of acrylic acid or methacrylic acid each having a linear or branched alkyl group.

The linear or branched alkyl group is preferably an alkyl group having 30 or less carbon atoms, more preferably an alkyl group having 1 to 20 carbon atoms, still more preferably an alkyl group having 4 to 18 carbon atoms. Specific examples of the alkyl group include a methyl group, an ethyl group, a propyl group, an isopropyl group, a n-butyl group, a t-butyl group, an isobutyl group, an amyl group, an isoamyl group, a hexyl group, a heptyl group, a cyclohexyl group, a 2-ethylhexyl group, an octyl group, an isooctyl group, a nonyl group, an isononyl group, a decyl group, an isodecyl group, an undecyl group, a lauryl group, a tridecyl group, a tetradecyl group, a stearyl group, an octadecyl group, and a dodecyl group.

Specific examples of the ester of acrylic acid or methacrylic acid having a linear or branched alkyl group include propyl (meth)acrylate, isopropyl (meth)acrylate, n-butyl (meth)acrylate, isobutyl (meth)acrylate, s-butyl (meth)acrylate, pentyl (meth)acrylate, isopentyl (meth)acrylate, hexyl (meth) acrylate, heptyl (meth) acrylate, 2-ethylhexyl (meth)acrylate, octyl (meth)acrylate, isooctyl (meth)acrylate, nonyl (meth)acrylate, isononyl (meth)acrylate, decyl (meth)acrylate, isodecyl (meth)acrylate, undecyl (meth)acrylate, dodecyl (meth)acrylate, tridecyl (meth)acrylate, tetradecyl (meth) acrylate, pentadecyl (meth) acrylate, hexadecyl (meth) acrylate, heptadecyl (meth) acrylate, octadecyl (meth)acrylate, nonadecyl (meth)acrylate, and eicosyl (meth) acrylate.

The monomer composition may contain another monomer copolymerizable with the alkyl (meth)acrylate as required for the purpose of modifying, for example, cohesive strength, heat resistance, or cross-linkability. Examples of such monomer include: carboxyl group-containing monomers, such as acrylic acid and methacrylic acid; acid anhydride monomers, such as maleic anhydride and itaconic anhydride; hydroxyl group-containing monomers, such as hydroxyethyl (meth)acrylate and hydroxypropyl (meth)acrylate; sulfonic acid group-containing monomers, such as styrenesulfonic acid and allylsulfonic acid; nitrogen-containing monomers, such as (meth)acrylamide, N,N-dimethyl (meth)acrylamide, and acryloylmorpholine; aminoalkyl (meth)acrylate-based monomers such as aminoethyl (meth)acrylate; alkoxyalkyl (meth)acrylate-based monomers such as methoxyethyl (meth)acrylate; maleimide-based monomers, such as N-cyclohexylmaleimide and N-isopropylmaleimide; itaconimide-based monomers, such as N-methylitaconimide and N-ethylitaconimide; succinimide-based monomers; vinyl-based monomers, such as vinyl acetate, vinyl propionate, N-vinylpyrrolidone, and methylvinylpyrrolidone; cyanoacrylate monomers, such as acrylonitrile and methacrylonitrile; epoxy group-containing acrylic monomers such as glycidyl (meth)acrylate; glycol-based acrylic ester monomers, such as polyethylene glycol (meth)acrylate and polypropylene glycol (meth)acrylate; acrylic acid ester-based monomers each having a heterocycle, a halogen atom, a silicon atom, or the like, such as tetrahydrofurfuryl (meth)acrylate, fluorine (meth)acrylate, and silicone (meth)acrylate; olefin-based monomers, such as isoprene, butadiene, and isobutylene; and vinyl ether-based monomers such as vinyl ether. Those monomer components may be used alone or in combination thereof. The content of the monomer is preferably from 1 part by weight to 30 parts by weight, more preferably from 3 parts by weight to 25 parts by weight with respect to 100 parts by weight of all the monomers of the monomer composition.

The weight-average molecular weight of the (meth)acrylic resin is preferably 300,000 or more, more preferably 500,000 or more, still more preferably from 600,000 to 2,000,000. When the weight-average molecular weight falls within such ranges, bleeding of a low-molecular-weight component can be prevented, and hence a pressure-sensitive adhesive sheet having a low contamination property can be obtained. The molecular weight distribution (weight-average molecular weight/number-average molecular weight) of the (meth)acrylic resin is preferably from 1 to 20, more preferably from 3 to 10. When a polymer having a narrow molecular weight distribution is used, bleeding of the low-molecular-weight component can be prevented, and hence a pressure-sensitive adhesive sheet having a low contamination property can be obtained. The weight-average molecular weight and the number-average molecular weight may be determined by gel permeation chromatography measurement (solvent: tetrahydrofuran, polystyrene equivalent).

The polymer having a carbon-carbon double bond may be obtained by any appropriate method. The polymer may be obtained by, for example, subjecting a resin obtained by any appropriate polymerization method and a compound having a polymerizable carbon-carbon double bond to a reaction (e.g., a condensation reaction or an addition reaction). Specifically, when the (meth)acrylic resin is used, the resin may be obtained by subjecting a (meth)acrylic resin (copolymer) having a structural unit derived from a monomer having any appropriate functional group to polymerization in any appropriate solvent, and then subjecting a functional group of the resultant acrylic resin and the compound having a polymerizable carbon-carbon double bond that may react with the functional group to a reaction. The amount of the compound having a polymerizable carbon-carbon double bond to be subjected to the reaction is preferably from 4 parts by weight to 30 parts by weight, more preferably from 4 parts by weight to 20 parts by weight with respect to 100 parts by weight of the above-mentioned resin. Any appropriate solvent may be used as the solvent. Examples thereof include various organic solvents, such as ethyl acetate, methyl ethyl ketone, and toluene.

When the resin and the compound having a polymerizable carbon-carbon double bond are subjected to a reaction as described above, the resin and the compound having a polymerizable carbon-carbon double bond preferably have functional groups that can react with each other. The combination of the functional groups is, for example, a carboxyl group/an epoxy group, a carboxyl group/an aziridine group, or a hydroxyl group/an isocyanate group. Of those combinations of the functional groups, a combination of a hydroxyl group and an isocyanate group is preferred from the viewpoint of ease of reaction tracking.

Examples of the compound having a carbon-carbon double bond include 2-isocyanatoethyl methacrylate, methacryloyl isocyanate, 2-methacryloyloxyethyl isocyanate (2-isocyanatoethyl methacrylate), and m-isopropenyl-α,α-dimethylbenzyl isocyanate.

When the pressure-sensitive adhesive obtained by adding the UV-curable monomer and/or oligomer is used, any appropriate monomer or oligomer may be used as each of the UV-curable monomer and oligomer. Examples of the UV-curable monomer include urethane (meth) acrylate, trimethylolpropane tri(meth)acrylate, tetramethylolmethane tetra(meth)acrylate, pentaerythritol tri(meth)acrylate, pentaerythritol tetra(meth)acrylate, dipentaerythritol monohydroxy penta(meth)acrylate, dipentaerythritol hexa(meth)acrylate, and 1,4-butanediol di(meth)acrylate. Examples of the UV-curable oligomer include a urethane-based oligomer, a polyether-based oligomer, a polyester-based oligomer, a polycarbonate-based oligomer, and a polybutadiene-based oligomer. An oligomer having a molecular weight of from about 100 to about 30,000 is preferably used as the oligomer. The monomers and the oligomers may be used alone or in combination thereof.

The monomer and/or oligomer may be used in any appropriate amount in accordance with the kind of the pressure-sensitive adhesive to be used. The amount of the monomer and/or oligomer to be used is, for example, preferably from 5 parts by weight to 500 parts by weight, more preferably from 40 parts by weight to 150 parts by weight with respect to 100 parts by weight of the base polymer for forming the pressure-sensitive adhesive.

C-2. Photopolymerization Initiator

Any appropriate initiator may be used as the photopolymerization initiator. Examples of the photopolymerization initiator include: acyl phosphine oxide-based photopolymerization initiators, such as ethyl 2,4,6-trimethylbenzylphenyl phosphinate and (2,4,6-trimethylbenzoyl)-phenylphosphine oxide; α-ketol-based compounds, such as 4-(2-hydroxyethoxy)phenyl(2-hydroxy-2-propyl) ketone, α-hydroxy-α,α′-dimethylacetophenone, 2-methyl-2-hydroxypropiophenone, and 1-hydroxycyclohexyl phenyl ketone; acetophenone-based compounds, such as methoxyacetophenone, 2,2-dimethoxy-2-phenylacetophenone, 2,2-diethoxyacetophenone, and 2-methyl-1-[4-(methylthio)-phenyl]-2-morpholinopropane-1; benzoin ether-based compounds, such as benzoin ethyl ether, benzoin isopropyl ether, and anisoin methyl ether; ketal-based compounds such as benzyl dimethyl ketal; aromatic sulfonyl chloride-based compounds such as 2-naphthalenesulfonyl chloride; photoactive oxime-based compounds such as 1-phenone-1,1-propanedione-2-(o-ethoxycarbonyl)oxime; benzophenone-based compounds, such as benzophenone, benzoylbenzoic acid, and 3,3′-dimethyl-4-methoxybenzophenone; thioxanthone-based compounds, such as thioxanthone, 2-chlorothioxanthone, 2-methylthioxanthone, 2,4-dimethylthioxanthone, isopropylthioxanthone, 2,4-dichlorothioxanthone, 2,4-diethylthioxanthone, and 2,4-diisopropylthioxanthone; camphorquinone; halogenated ketones; and acyl phosphonates, and α-hydroxyacetophenones such as 2-hydroxy-1-(4-(4-(2-hydroxy-2-methylpropionyl)benzyl)phenyl-2-methylpropane-1. Of those, acetophenone-based compounds may be preferably used. The photopolymerization initiators may be used alone or in combination thereof.

A commercially available product may be used as the photopolymerization initiator. Examples thereof include products available under the product names Omnirad 127 D, Omnirad 379 EG, and Omnirad 651 from IGM Resins B.V.

The photopolymerization initiator may be used in any appropriate amount. The content of the photopolymerization initiator is preferably from 0.5 part by weight to 20 parts by weight, more preferably from 0.5 part by weight to 10 parts by weight with respect to 100 parts by weight of the above-mentioned UV-curable pressure-sensitive adhesive. When the content of the photopolymerization initiator is less than 0.5 part by weight, the UV-curable pressure-sensitive adhesive may not be sufficiently cured at the time of UV irradiation. When the content of the photopolymerization initiator is more than 10 parts by weight, the storage stability of the pressure-sensitive adhesive may reduce.

C-3. Phosphoric Acid Ester-Based Surfactant

Examples of the phosphoric acid ester-based surfactant include a phosphoric acid monoester of a polyoxyethylene alkyl ether or a polyoxyethylene alkylaryl ether, a phosphoric acid diester of a polyoxyethylene alkyl ether or a polyoxyethylene alkylaryl ether, a phosphoric acid triester of a polyoxyethylene alkyl ether or a polyoxyethylene alkylaryl ether, an alkyl phosphoric acid ester, an alkyl ether phosphoric acid ester, and salts thereof. Examples of the salts include a sodium salt and a potassium salt. Of those, a polyoxyethylene alkyl ether phosphate and salts thereof, a monoester, a diester, or a mixture thereof may be preferably used. Those phosphoric acid ester-based surfactants may be used alone or in combination thereof.

A polyoxyethylene alkyl ether phosphate is a phosphoric acid ester of a product obtained by addition polymerization of ethylene oxide to a higher alcohol. The number of carbon atoms of the higher alcohol is preferably from 8 to 22, more preferably from 10 to 20, still more preferably from 12 to 18. The number of moles of ethylene oxide added is preferably from 1 to 15, more preferably from 2 to 12, still more preferably from 2 to 10. With such polyoxyethylene alkyl ether phosphate, even when a soft pressure-sensitive adhesive having excellent unevenness followability is adopted, the pressure-sensitive adhesive composition that can form a pressure-sensitive adhesive layer having an excellent anchoring force with the base material is obtained. As a result, even after the pressure-sensitive adhesive layer is subjected to UV curing, an adhesive residue on an adherend can be suppressed.

The content of the phosphoric acid ester-based surfactant is preferably 0.03 part by weight or more, more preferably from 0.1 part by weight to 1 part by weight, still more preferably from 0.3 part by weight to 0.5 part by weight with respect to 100 parts by weight of the base polymer. When the content of the phosphoric acid ester-based surfactant falls within such ranges, even when a soft pressure-sensitive adhesive having excellent unevenness followability is adopted, the pressure-sensitive adhesive composition that can form a pressure-sensitive adhesive layer having an excellent anchoring force with the base material is obtained. As a result, even after the pressure-sensitive adhesive layer is subjected to UV curing, an adhesive residue on an adherend can be suppressed.

C-4. Additive

The pressure-sensitive adhesive layer forming composition may contain any appropriate additive as required. Examples of the additive include a cross-linking agent, a catalyst (e.g., a platinum catalyst), a tackifier, a plasticizer, a pigment, a dye, a filler, an age resistor, a conductive material, a UV absorber, a light stabilizer, a release modifier, a softener, a surfactant except the phosphoric acid ester-based surfactant, a flame retardant, a solvent, and an oligomer.

In at least one embodiment of the present disclosure, the UV-curable pressure-sensitive adhesive further contains a cross-linking agent. Examples of the cross-linking agent include an isocyanate-based cross-linking agent, an epoxy-based cross-linking agent, an aziridine-based cross-linking agent, and a chelate-based cross-linking agent. The content ratio of the cross-linking agent is preferably 1 part by weight or less, more preferably from 0.01 part by weight to 1 part by weight, still more preferably from 0.02 part by weight to 0.6 part by weight, particularly preferably from 0.03 part by weight to 0.5 part by weight with respect to 100 parts by weight of the base polymer in the UV-curable pressure-sensitive adhesive. The flexibility of the pressure-sensitive adhesive layer can be controlled by the content ratio of the cross-linking agent. When the content of the cross-linking agent is less than 0.01 part by weight, the pressure-sensitive adhesive becomes sol, and hence the pressure-sensitive adhesive layer may not be formed. When the content of the cross-linking agent is more than 1 part by weight, followability to unevenness of an adherend surface may not be sufficiently obtained.

In at least one embodiment of the present disclosure, the isocyanate-based cross-linking agent is preferably used. The isocyanate-based cross-linking agent is preferred because the cross-linking agent can react with various kinds of functional groups. A cross-linking agent having 3 or more isocyanate groups is particularly preferably used. When the isocyanate-based cross-linking agent is used as the cross-linking agent and the content ratio of the cross-linking agent falls within the above-mentioned ranges, the UV-curable pressure-sensitive adhesive having excellent followability to unevenness of the adherend surface, and an excellent anchoring property with the base material can be provided.

The thickness of the pressure-sensitive adhesive layer may be set to any appropriate value. The thickness of the pressure-sensitive adhesive layer is preferably from 10 μm to 500 μm, more preferably from 15 μm to 300 μm, still more preferably from 20 μm to 250 μm. When the thickness of the pressure-sensitive adhesive layer falls within the above-mentioned ranges, sufficient pressure-sensitive adhesive strength to an adherend can be exhibited.

A gel fraction of the UV-curable pressure-sensitive adhesive is preferably from 20% to 99%, more preferably from 50% to 97%, still more preferably from 70% to 95%. The gel fraction may be determined as an insoluble content with respect to a solvent such as ethyl acetate. Specifically, the gel fraction is determined as a weight fraction (unit: wt %) of an insoluble component after the UV-curable pressure-sensitive adhesive is immersed in ethyl acetate at 23° C. for 7 days with respect to a sample before immersion. In general, the gel fraction of a polymer is equivalent to the cross-linking degree thereof, and a larger number of cross-linked moieties in the polymer means a larger gel fraction. The gel fraction (introduction amount of a cross-linked structure) may be adjusted to a desired range by a method of introducing the cross-linked structure, the kind and amount of the cross-linking agent, or the like.

D. Production Method for Pressure-Sensitive Adhesive Sheet for Semiconductor Processing

The pressure-sensitive adhesive sheet for semiconductor processing may be produced by any appropriate method. The pressure-sensitive adhesive sheet for semiconductor processing may be obtained by, for example, a method involving applying a pressure-sensitive adhesive solution (UV-curable pressure-sensitive adhesive) to a release liner, drying to form a pressure-sensitive adhesive layer on the release liner, and bonding the resultant to the base material. In addition, the pressure-sensitive adhesive sheet for semiconductor processing may be obtained by applying the UV-curable pressure-sensitive adhesive to the base material, followed by drying. Various methods, such as bar coating, air knife coating, gravure coating, gravure reverse coating, reverse roll coating, lip coating, die coating, dip coating, offset printing, flexographic printing, and screen printing, may each be adopted as a method of applying the pressure-sensitive adhesive layer forming composition. Any appropriate method may be adopted as a method for the drying.

E. Usage of Pressure-Sensitive Adhesive Sheet for Semiconductor Processing

The pressure-sensitive adhesive sheet for semiconductor processing can be suitably used in a semiconductor production process. As described above, even when the pressure-sensitive adhesive sheet for semiconductor processing according to at least one embodiment of the present disclosure is brought into contact with a solvent, a reduction in anchoring force between the base material and pressure-sensitive adhesive layer of the sheet can be suppressed. Accordingly, the pressure-sensitive adhesive sheet for semiconductor processing can also be suitably used in a semiconductor production process including a solvent washing step. Examples of the solvent to be used in the solvent washing step include solvents each typically used in a production method for a semiconductor, such as 2,2-bis(hydroxymethyl)propionic acid (DBPA), propylene glycol monomethyl ether (PGME), propylene glycol monomethyl ether acetate (PGMEA), isopropanol (IPA), N,N-dimethylpropionamide, N-methyl-2-pyrrolidone (NMP), and butyl acetate.

As described above, the pressure-sensitive adhesive sheet for semiconductor processing according to at least one embodiment of the present disclosure has excellent followability to unevenness. Accordingly, the semiconductor wafer having unevenness on its surface can be appropriately retained in the production process. For example, the sheet can also be suitably used in a process for producing a semiconductor having a more complex structure such as a dynamic random access memory (DRAM) obtained by laminating a through silicon via (TSV) chip. The pressure-sensitive adhesive sheet for semiconductor processing according to at least one embodiment of the present disclosure can be suitably used as a dicing tape of a semiconductor wafer having an uneven structure on its surface.

### EXAMPLES

The present disclosure is specifically described below by way of examples, but the present disclosure is not limited to these examples. In addition, “part(s)” and “%” in the examples are by weight unless otherwise stated.

### [Production Example 1] Preparation of Base Polymer 1

100 parts by weight of dodecyl methacrylate (LMA), 22 parts by weight of hexyl methacrylate (HMA), 0.2 part by weight of a polymerization initiator (azobisisobutyronitrile (AIBN)), and 500 parts by weight of ethyl acetate were mixed to prepare a composition. The resultant composition was loaded into an experimental apparatus for polymerization including a 1-liter round-bottom separable flask provided with a separable cover, a separating funnel, a temperature gauge, a nitrogen-introducing tube, a Liebig condenser, a vacuum seal, a stirring rod, and a stirring blade. While the composition was stirred, the apparatus was purged with nitrogen at normal temperature for 6 hours. After that, while the composition was stirred in a stream of nitrogen, the composition was held at 65° C. for 4 hours and then at 75° C. for 2 hours for polymerization. Thus, a resin solution of a base polymer 1 (solid content: 20%) was obtained.

### [Production Example 2] Preparation of Base Polymer 2

75 parts by weight of 2-ethylhexyl acrylate (2EHA), 25 parts by weight of acryloylmorpholine (ACMO), 22 parts by weight 2-hydroxyethyl acrylate (HEA), 0.2 part by weight of a polymerization initiator (azobisisobutyronitrile (AIBN)), and 500 parts by weight of ethyl acetate were mixed to prepare a composition. The resultant composition was loaded into an experimental apparatus for polymerization including a 1-liter round-bottom separable flask provided with a separable cover, a separating funnel, a temperature gauge, a nitrogen-introducing tube, a Liebig condenser, a vacuum seal, a stirring rod, and a stirring blade. While the composition was stirred, the apparatus was purged with nitrogen at normal temperature for 6 hours. After that, while the composition was stirred in a stream of nitrogen, the composition was held at 65° C. for 4 hours and then at 75° C. for 2 hours for polymerization. Thus, a resin solution of a base polymer 2 (solid content: 20%) was obtained.

### [Production Example 3] Preparation of Base Polymer 3

75 parts by weight of 2-methoxyethyl acrylate (MEA), 20 parts by weight of ACMO, 20 parts by weight of HEA, 0.2 part by weight of a polymerization initiator (azobisisobutyronitrile (AIBN)), and 500 parts by weight of ethyl acetate were mixed to prepare a composition. The resultant composition was loaded into an experimental apparatus for polymerization including a 1-liter round-bottom separable flask provided with a separable cover, a separating funnel, a temperature gauge, a nitrogen-introducing tube, a Liebig condenser, a vacuum seal, a stirring rod, and a stirring blade. While the composition was stirred, the apparatus was purged with nitrogen at normal temperature for 6 hours. After that, while the composition was stirred in a stream of nitrogen, the composition was held at 65° C. for 4 hours and then at 75° C. for 2 hours for polymerization. Thus, a resin solution of a base polymer 3 (solid content: 19%) was obtained.

### [Production Example 4] Preparation of Base Polymer 4

50 parts by weight of ethyl acrylate (EA), 50 parts by weight of butyl acrylate (BA), 20 parts by weight of HEA, 0.2 part by weight of a polymerization initiator (azobisisobutyronitrile (AIBN)), and 500 parts by weight of ethyl acetate were mixed to prepare a composition. The resultant composition was loaded into an experimental apparatus for polymerization including a 1-liter round-bottom separable flask provided with a separable cover, a separating funnel, a temperature gauge, a nitrogen-introducing tube, a Liebig condenser, a vacuum seal, a stirring rod, and a stirring blade. While the composition was stirred, the apparatus was purged with nitrogen at normal temperature for 6 hours. After that, while the composition was stirred in a stream of nitrogen, the composition was held at 65° C. for 4 hours and then at 75° C. for 2 hours for polymerization. Thus, a resin solution of a base polymer 4 (solid content: 20%) was obtained.

### Example 1

1. Preparation of UV-Curable Pressure-Sensitive Adhesive Composition

0.5 part by weight of a polyisocyanate cross-linking agent 1 (manufactured by Nippon Polyurethane Industry Co., Ltd., product name: “CORONATE L”), 0.3 part by weight of a phosphoric acid ester-based surfactant 1 (manufactured by Toho Chemical Industry Co., Ltd., product name: “PHOSPHANOL RL-210”), and 3 parts by weight of a photopolymerization initiator (manufactured by IGM Resins B.V., product name: “Omnirad 127 D”) were added to 100 parts by weight of the solid content of the resin solution of the base polymer 1 obtained in Production Example 1, followed by mixing. Next, ethyl acetate was used as a diluting solvent to adjust the viscosity of the mixture. Thus, a UV-curable pressure-sensitive adhesive 1 was obtained.

2. Production of Pressure-Sensitive Adhesive Sheet for Semiconductor Processing

A film having a three-layer structure of polypropylene (PP)/ethylene vinyl acetate (EVA)/polypropylene (PP) (manufactured by Kurabo Industries Ltd., thickness: 80 μm) was used as a base material. The UV-curable pressure-sensitive adhesive composition 1 obtained above was applied to one surface of the base material, followed by drying to form a pressure-sensitive adhesive layer having a thickness of 20 μm. Thus, a pressure-sensitive adhesive sheet for semiconductor processing was produced.

### Example 2

A UV-curable pressure-sensitive adhesive composition 2 was prepared in the same manner as in Example 1 except that a phosphoric acid ester-based surfactant 2 (manufactured by Toho Chemical Industry Co., Ltd., product name: “PHOSPHANOL ML-220”) was used in place of the phosphoric acid ester-based surfactant 1. A pressure-sensitive adhesive sheet for semiconductor processing was produced in the same manner as in Example 1 except that a pressure-sensitive adhesive layer was formed using the UV-curable pressure-sensitive adhesive composition 2.

### Example 3

A UV-curable pressure-sensitive adhesive composition 3 was prepared in the same manner as in Example 1 except that a phosphoric acid ester-based surfactant 3 (manufactured by Toho Chemical Industry Co., Ltd., product name: “PHOSPHANOL RL-310”) was used in place of the phosphoric acid ester-based surfactant 1. A pressure-sensitive adhesive sheet for semiconductor processing was produced in the same manner as in Example 1 except that a pressure-sensitive adhesive layer was formed using the UV-curable pressure-sensitive adhesive composition 3.

### Example 4

A UV-curable pressure-sensitive adhesive composition 4 was prepared in the same manner as in Example 1 except that a phosphoric acid ester-based surfactant 4 (manufactured by Toho Chemical Industry Co., Ltd., product name: “PHOSPHANOL RS-410”) was used in place of the phosphoric acid ester-based surfactant 1. A pressure-sensitive adhesive sheet for semiconductor processing was produced in the same manner as in Example 1 except that a pressure-sensitive adhesive layer was formed using the UV-curable pressure-sensitive adhesive composition 4.

### Example 5

A UV-curable pressure-sensitive adhesive composition 5 was prepared in the same manner as in Example 1 except that a phosphoric acid ester-based surfactant 5 (manufactured by Toho Chemical Industry Co., Ltd., product name: “PHOSPHANOL RS-710”) was used in place of the phosphoric acid ester-based surfactant 1. A pressure-sensitive adhesive sheet for semiconductor processing was produced in the same manner as in Example 1 except that a pressure-sensitive adhesive layer was formed using the UV-curable pressure-sensitive adhesive composition 5.

### Example 6

A UV-curable pressure-sensitive adhesive composition 6 was prepared in the same manner as in Example 1 except that the addition amount of the phosphoric acid ester-based surfactant 1 was changed to 0.03 part by weight. A pressure-sensitive adhesive sheet for semiconductor processing was produced in the same manner as in Example 1 except that a pressure-sensitive adhesive layer was formed using the UV-curable pressure-sensitive adhesive composition 6.

### Example 7

A UV-curable pressure-sensitive adhesive composition 7 was prepared in the same manner as in Example 1 except that the addition amount of the phosphoric acid ester-based surfactant 1 was changed to 0.1 part by weight. A pressure-sensitive adhesive sheet for semiconductor processing was produced in the same manner as in Example 1 except that a pressure-sensitive adhesive layer was formed using the UV-curable pressure-sensitive adhesive composition 7.

### Example 8

A UV-curable pressure-sensitive adhesive composition 8 was prepared in the same manner as in Example 1 except that the addition amount of the phosphoric acid ester-based surfactant 1 was changed to 0.6 part by weight. A pressure-sensitive adhesive sheet for semiconductor processing was produced in the same manner as in Example 1 except that a pressure-sensitive adhesive layer was formed using the UV-curable pressure-sensitive adhesive composition 8.

### Example 9

A UV-curable pressure-sensitive adhesive composition 9 was prepared in the same manner as in Example 1 except that the addition amount of the phosphoric acid ester-based surfactant 1 was changed to 1 part by weight. A pressure-sensitive adhesive sheet for semiconductor processing was produced in the same manner as in Example 1 except that a pressure-sensitive adhesive layer was formed using the UV-curable pressure-sensitive adhesive composition 9.

### Example 10

A UV-curable pressure-sensitive adhesive composition 10 was prepared in the same manner as in Example 1 except that the base polymer 2 was used in place of the base polymer 1; 0.1 part by weight of a cross-linking agent 2 (manufactured by Mitsui Chemicals Inc., product name: “TAKENATE D-101A”) was used in place of the cross-linking agent 1; and the addition amount of the phosphoric acid ester-based surfactant 1 was changed to 0.5 part by weight. A pressure-sensitive adhesive sheet for semiconductor processing was produced in the same manner as in Example 1 except that a pressure-sensitive adhesive layer was formed using the UV-curable pressure-sensitive adhesive composition 10.

### Example 11

A UV-curable pressure-sensitive adhesive composition 11 was prepared in the same manner as in Example 10 except that the addition amount of the cross-linking agent 2 was changed to 0.3 part by weight. A pressure-sensitive adhesive sheet for semiconductor processing was produced in the same manner as in Example 1 except that a pressure-sensitive adhesive layer was formed using the UV-curable pressure-sensitive adhesive composition 11.

### Example 12

A UV-curable pressure-sensitive adhesive composition 12 was prepared in the same manner as in Example 10 except that the addition amount of the cross-linking agent 2 was changed to 0.5 part by weight. A pressure-sensitive adhesive sheet for semiconductor processing was produced in the same manner as in Example 1 except that a pressure-sensitive adhesive layer was formed using the UV-curable pressure-sensitive adhesive composition 12.

### Example 13

A UV-curable pressure-sensitive adhesive composition 13 was prepared in the same manner as in Example 10 except that the addition amount of the cross-linking agent 2 was changed to 1 part by weight. A pressure-sensitive adhesive sheet for semiconductor processing was produced in the same manner as in Example 1 except that a pressure-sensitive adhesive layer was formed using the UV-curable pressure-sensitive adhesive composition 13.

### Example 14

A UV-curable pressure-sensitive adhesive composition 14 was prepared in the same manner as in Example 12 except that the base polymer 3 was used in place of the base polymer 2. A pressure-sensitive adhesive sheet for semiconductor processing was produced in the same manner as in Example 1 except that a pressure-sensitive adhesive layer was formed using the UV-curable pressure-sensitive adhesive composition 14.

### Example 15

A UV-curable pressure-sensitive adhesive composition 15 was prepared in the same manner as in Example 12 except that the base polymer 4 was used in place of the base polymer 2. A pressure-sensitive adhesive sheet for semiconductor processing was produced in the same manner as in Example 1 except that a pressure-sensitive adhesive layer was formed using the UV-curable pressure-sensitive adhesive composition 15.

### Example 16

A pressure-sensitive adhesive sheet for semiconductor processing was produced in the same manner as in Example 12 except that a single-layer film of polyethylene (PE) (manufactured by Okura Industrial Co., Ltd., product name: “NSO FILM”) was used as the base material.

### Example 17

A pressure-sensitive adhesive sheet for semiconductor processing was produced in the same manner as in Example 12 except that a single-layer film of polyethylene terephthalate (PET) (manufactured by Toray Industries, Inc., product name: “Lumirror #50 S105”) was used as the base material.

### Example 18

A UV-curable pressure-sensitive adhesive composition 18 was prepared in the same manner as in Example 12 except that the base polymer 1 was used in place of the base polymer 2, and 3 parts by weight of a light release agent (polypropylene glycol) and 5 parts by weight of a polyfunctional oligomer (urethane acrylate, manufactured by The Nippon Synthetic Chemical Industry Co., Ltd., product name: “UV-3000TL”) were further added. A pressure-sensitive adhesive sheet for semiconductor processing was produced in the same manner as in Example 1 except that a pressure-sensitive adhesive layer was formed using the UV-curable pressure-sensitive adhesive composition 18.

### Comparative Example 1

A UV-curable pressure-sensitive adhesive composition C1 was prepared in the same manner as in Example 1 except that the phosphoric acid ester-based surfactant 1 was not added. A pressure-sensitive adhesive sheet for semiconductor processing was produced in the same manner as in Example 1 except that a pressure-sensitive adhesive layer was formed using the UV-curable pressure-sensitive adhesive composition C1.

### Comparative Example 2

A UV-curable pressure-sensitive adhesive composition C2 was prepared in the same manner as in Example 1 except that 0.3 part by weight of an alkyl sulfate-type surfactant 1 (manufactured by Toho Chemical Industry Co., Ltd., product name: “ALSCOAP NS-230”) was added in place of the phosphoric acid ester-based surfactant 1. A pressure-sensitive adhesive sheet for semiconductor processing was produced in the same manner as in Example 1 except that a pressure-sensitive adhesive layer was formed using the UV-curable pressure-sensitive adhesive composition C2.

### Comparative Example 3

A UV-curable pressure-sensitive adhesive composition C3 was prepared in the same manner as in Example 1 except that 0.3 part by weight of an alkyl sulfate-type surfactant 2 (manufactured by Toho Chemical Industry Co., Ltd., product name: “ALSCOAP TH-330K”) was added in place of the phosphoric acid ester-based surfactant 1. A pressure-sensitive adhesive sheet for semiconductor processing was produced in the same manner as in Example 1 except that a pressure-sensitive adhesive layer was formed using the UV-curable pressure-sensitive adhesive composition C3.

### Comparative Example 4

A UV-curable pressure-sensitive adhesive composition C4 was prepared in the same manner as in Example 1 except that 0.3 part by weight of a sulfonic acid-type surfactant (manufactured by Toho Chemical Industry Co., Ltd., product name: “LUNOX S-40TD”) was added in place of the phosphoric acid ester-based surfactant 1. A pressure-sensitive adhesive sheet for semiconductor processing was produced in the same manner as in Example 1 except that a pressure-sensitive adhesive layer was formed using the UV-curable pressure-sensitive adhesive composition C4.

### Comparative Example 5

A UV-curable pressure-sensitive adhesive composition C5 was prepared in the same manner as in Example 1 except that 0.3 part by weight of a polyoxyethylene alkyl ether-type surfactant (manufactured by Toho Chemical Industry Co., Ltd., product name: “PEGNOL S-4DV”) was added in place of the phosphoric acid ester-based surfactant 1. A pressure-sensitive adhesive sheet for semiconductor processing was produced in the same manner as in Example 1 except that a pressure-sensitive adhesive layer was formed using the UV-curable pressure-sensitive adhesive composition C5.

### Comparative Example 6

A UV-curable pressure-sensitive adhesive composition C6 was prepared in the same manner as in Example 10 except that the addition amount of the cross-linking agent 2 was changed to 0.01 part by weight. A pressure-sensitive adhesive sheet for semiconductor processing was produced in the same manner as in Example 1 except that a pressure-sensitive adhesive layer was formed using the UV-curable pressure-sensitive adhesive composition C6.

### Comparative Example 7

A UV-curable pressure-sensitive adhesive composition C7 was prepared in the same manner as in Example 12 except that no phosphoric acid ester-based surfactant was added. A pressure-sensitive adhesive sheet for semiconductor processing was produced in the same manner as in Example 1 except that a pressure-sensitive adhesive layer was formed using the UV-curable pressure-sensitive adhesive composition C7.

### Comparative Example 8

A UV-curable pressure-sensitive adhesive composition C8 was prepared in the same manner as in Example 12 except that no phosphoric acid ester-based surfactant was added; and the addition amount of the cross-linking agent 2 was changed to 3 parts by weight. A pressure-sensitive adhesive sheet for semiconductor processing was produced in the same manner as in Example 1 except that a pressure-sensitive adhesive layer was formed using the UV-curable pressure-sensitive adhesive composition C8.

### Comparative Example 9

A UV-curable pressure-sensitive adhesive composition C9 was prepared in the same manner as in Example 12 except that no phosphoric acid ester-based surfactant was added; and the addition amount of the cross-linking agent 2 was changed to 5 parts by weight. A pressure-sensitive adhesive sheet for semiconductor processing was produced in the same manner as in Example 1 except that a pressure-sensitive adhesive layer was formed using the UV-curable pressure-sensitive adhesive composition C9.

### Comparative Example 10

A UV-curable pressure-sensitive adhesive composition C10 was prepared in the same manner as in Example 16 except that no phosphoric acid ester-based surfactant was added. A pressure-sensitive adhesive sheet for semiconductor processing was produced in the same manner as in Example 17 except that a pressure-sensitive adhesive layer was formed using the UV-curable pressure-sensitive adhesive composition C10.

### Comparative Example 11

A UV-curable pressure-sensitive adhesive composition C11 was prepared in the same manner as in Example 17 except that no phosphoric acid ester-based surfactant was added. A pressure-sensitive adhesive sheet for semiconductor processing was produced in the same manner as in Example 18 except that a pressure-sensitive adhesive layer was formed using the UV-curable pressure-sensitive adhesive composition C11.

### Comparative Example 12

A UV-curable pressure-sensitive adhesive composition C12 was prepared in the same manner as in Example 18 except that no phosphoric acid ester-based surfactant was added. A pressure-sensitive adhesive sheet for semiconductor processing was produced in the same manner as in Example 19 except that a pressure-sensitive adhesive layer was formed using the UV-curable pressure-sensitive adhesive composition C12.

<Evaluation>

The following evaluations were performed using the pressure-sensitive adhesive sheets obtained in Examples and Comparative Examples. The results are shown in Table 1 and Table 2.

1. Modulus of Elasticity of Pressure-Sensitive Adhesive Layer

A modulus of elasticity of the pressure-sensitive adhesive layer of the pressure-sensitive adhesive sheet obtained in each of Examples or Comparative Examples was measured with a nanoindenter (manufactured by Hysitron, Inc., product name: “TriboIndenter”). A conical (spherical; radius: 10 μm) indenter was used, and single indentation measurement was performed. The measurement was performed under a light-shielding environment by setting a measurement temperature to 25° C., an indentation depth to 2,000 nm, and an indentation rate and a drawing rate to 1,000 nm/s. The obtained load (μN) and displacement (nm) were analyzed by a JKR method, and the modulus of elasticity was calculated by the following equation.

$${E}_{r} = {[ \frac{{4}^{2 / 3} + 1}{{48}^{1 / 3}} ]}^{3 / 2} [ \frac{{P}_{min}}{{{R}^{1 / 2} ( {h}_{{P}^{0}} - {h}_{Pmin} )}^{3 / 2}} ]$$

Eᵣ: modulus of elasticity
R: indenter radius
h: displacement
P: load

2. Peel Strength

(1) Pressure-Sensitive Adhesive Strength Before UV Irradiation (Before UV)

The pressure-sensitive adhesive sheet obtained in each of Examples or Comparative Examples was cut into a strip shape measuring 150 mm long by 20 mm wide. Under 23° C., a 2-kilogram roller was reciprocated once to bond the pressure-sensitive adhesive layer of the pressure-sensitive adhesive sheet to a mirror-finished silicon wafer (manufactured by Shin-Etsu Handotai Co., Ltd., product name: “CZN<100>2.5-3.5,” diameter: 4 inches). The bonding portion between the sheet and the wafer was formed so as to measure 80 mm long by 20 mm wide. Then, the bonded product was left at rest with no load under an atmosphere at 23° C. for 30 minutes. Next, the pressure-sensitive adhesive strength of the pressure-sensitive adhesive sheet was measured by performing a 90° peel test in conformity with JIS Z 0237 under the following conditions.

<90° Peel Test>
Number of repetitions of test: 3 times
Temperature: 23° C.
Peel angle: 90°
Tensile rate: 300 mm/min
Initial length (chuck interval): 150 mm

(2) Pressure-Sensitive Adhesive Strength after UV Irradiation (after UV)

The pressure-sensitive adhesive sheet obtained in each of Examples or Comparative Examples was cut into a strip shape measuring 150 mm long by 20 mm wide. Under 23° C., a 2-kilogram roller was reciprocated once to bond the pressure-sensitive adhesive sheet from which its separator had been peeled to a mirror-finished silicon wafer (manufactured by Shin-Etsu Handotai Co., Ltd., product name: “CZN<100>2.5-3.5,” diameter: 4 inches). The bonding portion between the sheet and the wafer was formed so as to measure 80 mm long by 20 mm wide. Then, the bonded product was left at rest with no load under an atmosphere at 23° C. for 30 minutes. After having been left at rest for 30 minutes, the bonded product was irradiated with UV light from the back surface side of the base material of the pressure-sensitive adhesive sheet under the following UV irradiation conditions. After that, the bonded product was left at rest for 30 minutes, and a 90° peel test was performed in conformity with JIS Z 0237 in the same manner as in the evaluation of the above-mentioned section (1).

<UV Irradiation Conditions>
UV irradiation apparatus: manufactured by Nitto Seiki Co., Ltd., product name: UM810
Light source: high-pressure mercury lamp
Irradiation intensity: 46 mW/cm 2 (measuring apparatus: “UV Intensity Meter UT-101” manufactured by Ushio Inc.)
Irradiation time: 10 sec
Integrated light quantity: 460 mJ

3. Anchoring Force

Anchoring Force Before UV Irradiation (Before UV)

The pressure-sensitive adhesive sheet for semiconductor processing obtained in each of Examples or Comparative Examples was cut out into a size of 20 mm wide by 150 mm long. A stainless steel (SUS) plate was bonded to the entirety of a back surface (surface on which the pressure-sensitive adhesive layer was not formed) of a base material of the pressure-sensitive adhesive sheet that was cut out via a double-sided tape (manufactured by Nitto Denko Corporation, product name: “No. 5000NS”). Next, a pressure-sensitive adhesive surface of a pressure-sensitive adhesive tape having a size of 20 mm wide by 150 mm long (manufactured by Nitto Denko Corporation, product name: “No. 315 Tape” (BT-315)) was bonded to the pressure-sensitive adhesive layer (surface not in contact with the base material) of the pressure-sensitive adhesive sheet to provide an evaluation sample. Next, a peel force between the base material and the pressure-sensitive adhesive layer of the evaluation sample was measured by a tensile test. The preparation and tensile test of the evaluation sample were each performed under an environmental temperature of 23° C. For the measurement of the peel force, the tensile test was performed under the conditions of a tensile rate of 300 mm/min and a peel angle of 180°.

(2) Anchoring Force after UV Irradiation (after UV)

The pressure-sensitive adhesive sheet for semiconductor processing obtained in each of Examples or Comparative Examples was cut out into a size of 20 mm wide by 150 mm long. A SUS plate was bonded to the entirety of a back surface (surface on which the pressure-sensitive adhesive layer was not formed) of a base material of the pressure-sensitive adhesive sheet that was cut out via a double-sided tape (manufactured by Nitto Denko Corporation, product name: “No. 5000NS”). Next, a pressure-sensitive adhesive surface of a pressure-sensitive adhesive tape having a size of 20 mm wide by 150 mm long (manufactured by Nitto Denko Corporation, product name: “No. 315 Tape” (BT-315)) was bonded to the pressure-sensitive adhesive layer (surface not in contact with the base material) of the pressure-sensitive adhesive sheet to provide an evaluation sample. Next, the bonded product was irradiated with UV light from the pressure-sensitive adhesive tape side under the following UV irradiation conditions. Then, the product was left at rest for 30 minutes, and a peel force between the base material and the pressure-sensitive adhesive layer of the evaluation sample was measured by a tensile test. The preparation and tensile test of the evaluation sample were each performed under an environmental temperature of 23° C. For the measurement of the peel force, the tensile test was performed under the conditions of a tensile rate of 300 mm/min and a peel angle of 180°. In addition, a breaking mode of the pressure-sensitive adhesive sheet after the peeling was visually observed, and was evaluated as follows: the case in which the peeling occurred at an interface between the pressure-sensitive adhesive sheet for semiconductor processing obtained in each of Examples or Comparative Examples and the pressure-sensitive adhesive tape bonded to the pressure-sensitive adhesive layer (case in which interfacial failure occurred) was indicated by “Interfacial,” and the case in which the pressure-sensitive adhesive sheet for semiconductor processing obtained in each of Examples or Comparative Examples and the pressure-sensitive adhesive layer adhered to the pressure-sensitive adhesive layer side of the pressure-sensitive adhesive tape bonded to the pressure-sensitive adhesive layer (case in which anchoring failure occurred) was indicated by “Anchoring”.

<UV Irradiation Conditions>
UV irradiation apparatus: manufactured by Nitto Seiki Co., Ltd., product name: UM810
Light source: high-pressure mercury lamp
Irradiation intensity: 46 mW/cm 2 (measuring apparatus: manufactured by Ushio Inc., product name: “UV Intensity Meter UT-101”)
Irradiation time: 10 sec
Integrated light quantity: 460 mJ

4. Embedding of Base Material

The presence or absence of air gaps in an interlayer region between the base material and the pressure-sensitive adhesive layer was observed with a microscope (manufactured by Keyence Corporation, product name: VK-X200, 10× objective lens) from the base material side of the pressure-sensitive adhesive sheet for semiconductor processing obtained in each of Examples or Comparative Examples.

5. Embedding of Adherend

The pressure-sensitive adhesive sheet obtained in each of Examples or Comparative Examples was mounted to a through-silicon via (TSV) wafer (pillar: 5 82 mt, 20 μmφ) with a vacuum mounter (manufactured by Nitto Seiki Co., Ltd., product name: “MSA-840V3”). Next, the presence or absence of air gaps between the pressure-sensitive adhesive layer and the pillar was observed from the back surface of the base material of the pressure-sensitive adhesive sheet with a microscope (manufactured by Keyence Corporation, product name: “VK-X200,” 10× objective lens).

6. Pick-Up (Adhesive Residue)

The pressure-sensitive adhesive tape was mounted to a TSV wafer (pillar: 5 μmt, 20 μmφ) with a vacuum mounter (manufactured by Nitto Seiki Co., Ltd., product name: “MSA-840V3”). Next, dicing of the TSV wafer was performed with a dicer (manufactured by DISCO Corporation, product name: “DFD6450”), to thereby cut the wafer into small pieces of 10 mm by 10 mm. Next, pick-up of the wafer that had been cut into small pieces was performed with a die sorter (manufactured by Canon Machinery Inc., product name: “BESTEM-S500”). A back surface (surface in contact with the pressure-sensitive adhesive layer of the pressure-sensitive adhesive tape) of the chip that has been subjected to the pick-up was observed with a microscope (manufactured by Keyence Corporation, product name: “VK-X200,” 10× objective lens), and the presence or absence of an adhesive residue on the chip was observed.

TABLE 1

| | | | Example 1 | Example 2 | Example 3 | Example 4 | Example 5 | Example 6 |
|---|---|---|---|---|---|---|---|---|
| Pressure- | Pressure- | Polymer | Polymer 1 | Polymer 1 | Polymer 1 | Polymer 1 | Polymer 1 | Polymer 1 |
| sensitive | sensitive | Number of parts | 100 | 100 | 100 | 100 | 100 | 100 |
| adhesive sheet | adhesive layer | Cross-linking | C/L | C/L | C/L | C/L | C/L | C/L |
| | | agent | | | | | | |
| | | Number of parts | 0.5 | 0.5 | 0.5 | 0.5 | 0.5 | 0.5 |
| | | Surfactant | RL-210 | ML-220 | RL-310 | RS-410 | RS-710 | RL-210 |
| | | (Phosphoric acid | | | | | | |
| | | ester) | | | | | | |
| | | Number of parts | 0.3 | 0.3 | 0.3 | 0.3 | 0.3 | 0.03 |
| | | Photopolymerization | Omn 127D | Omn 127D | Omn 127D | Omn 127D | Omn 127D | Omn 127D |
| | | initiator | | | | | | |
| | | Number of parts | 3 | 3 | 3 | 3 | 3 | 3 |
| | | Additive 1 | — | — | — | — | — | — |
| | | Number of parts | — | — | — | — | — | — |
| | | Additive 2 | — | — | — | — | — | — |
| | | Number of parts | — | — | — | — | — | — |
| | Base material | | *PP | *PP | *PP | *PP | *PP | *PP |
| Evaluation | Pressure- | Modulus of | 0.234 | 0.247 | 0.245 | 0.213 | 0.212 | 0.319 |
| | sensitive | elasticity before | | | | | | |
| | adhesive layer | UV (MPa) | | | | | | |
| | SS | | | | | | | |
| | With respect to | Before UV | 2.397 | 2.098 | 2.666 | 2.400 | 2.386 | 2.885 |
| | Si (90° peel) | After UV (460 mJ) | 0.019 | 0.018 | 0.021 | 0.023 | 0.027 | 0.020 |
| | Anchoring force | Before UV | 4.5 | 7.8 | 8.3 | 7.9 | 8.1 | 7.3 |
| | (using BT-315) | After UV (460 mJ) | 6.4 | 6.8 | 6.0 | 6.6 | 6.4 | 2.2 |
| | Breaking mode at anchoring force | | Interfacial | Interfacial | Interfacial | Interfacial | Interfacial | Anchoring |
| | after UV | | | | | | | |
| | Embedding of base material | | o | o | o | o | o | o |
| | | | (good) | (good) | (good) | (good) | (good) | (good) |
| | Embedding of adherend | | o | o | o | o | o | o |
| | | | (good) | (good) | (good) | (good) | (good) | (good) |
| | Pick-up (adhesive residue) | | o | o | o | o | o | o |
| | | | (good) | (good) | (good) | (good) | (good) | (good) |
| | | | Example 7 | Example 8 | Example 9 | Example 10 | Example 11 | Example 12 |
| Pressure- | Pressure- | Polymer | Polymer 1 | Polymer 1 | Polymer 1 | Polymer 2 | Polymer 2 | Polymer 2 |
| sensitive | sensitive | Number of parts | 100 | 100 | 100 | 100 | 100 | 100 |
| adhesive sheet | adhesive layer | Cross-linking | C/L | C/L | C/L | TAKENATE | TAKENATE | TAKENATE |
| | | agent | | | | | | |
| | | Number of parts | 0.5 | 0.5 | 0.5 | 0.1 | 0.3 | 0.5 |
| | | Surfactant | RL-210 | RL-210 | RL-210 | RL-210 | RL-210 | RL-210 |
| | | (Phosphoric acid | | | | | | |
| | | ester) | | | | | | |
| | | Number of parts | 0.1 | 0.6 | 1 | 0.5 | 0.5 | 0.5 |
| | | Photopolymerization | Omn 127D | Omn 127D | Omn 127D | Omn 127D | Omn 127D | Omn 127D |
| | | initiator | | | | | | |
| | | Number of parts | 3 | 3 | 3 | 3 | 3 | 3 |
| | | Additive 1 | — | — | — | — | — | — |
| | | Number of parts | — | — | — | — | — | — |
| | | Additive 2 | — | — | — | — | — | — |
| | | Number of parts | — | — | — | — | — | — |
| | Base material | | *PP | *PP | *PP | *PP | *PP | *PP |
| Evaluation | Pressure- | Modulus of | 0.267 | 0.195 | 0.167 | 0.362 | 0.425 | 0.579 |
| | sensitive | elasticity before | | | | | | |
| | adhesive layer | UV (MPa) | | | | | | |
| | SS | | | | | | | |
| | With respect to | Before UV | 2.547 | 1.335 | 1.057 | 2.779 | 2.605 | 2.500 |
| | Si (90° peel) | After UV (460 mJ) | 0.016 | 0.006 | 0.005 | 0.05 | 0.055 | 0.052 |
| | Anchoring force | Before UV | 7.8 | 3.2 | 2.8 | 7.1 | 7.7 | 6.6 |
| | (using BT-315) | After UV (460 mJ) | 6.8 | 3.2 | 2.8 | 2.2 | 5.0 | 5.1 |
| | Breaking mode at anchoring force | | Interfacial | Interfacial | Interfacial | Anchoring | Interfacial | Interfacial |
| | after UV | | | | | | | |
| | Embedding of base material | | o | o | o | o | o | o |
| | | | (good) | (good) | (good) | (good) | (good) | (good) |
| | Embedding of adherend | | o | o | o | o | o | o |
| | | | (good) | (good) | (good) | (good) | (good) | (good) |
| | Pick-up (adhesive residue) | | o | o | o | o | o | o |
| | | | (good) | (good) | (good) | (good) | (good) | (good) |
| | | | Example 13 | Example 14 | Example 15 | Example 16 | Example 17 | Example 18 |
| Pressure- | Pressure- | Polymer | Polymer 2 | Polymer 3 | Polymer 4 | Polymer 2 | Polymer 2 | Polymer 1 |
| sensitive | sensitive | Number of parts | 100 | 100 | 100 | 100 | 100 | 100 |
| adhesive sheet | adhesive layer | Cross-linking | TAKENATE | TAKENATE | TAKENATE | TAKENATE | TAKENATE | TAKENATE |
| | | agent | | | | | | |
| | | Number of parts | 1 | 0.5 | 0.5 | 0.5 | 0.5 | 0.5 |
| | | Surfactant | RL-210 | RL-210 | RL-210 | RL-210 | RL-210 | RL-210 |
| | | (Phosphoric acid | | | | | | |
| | | ester) | | | | | | |
| | | Number of parts | 0.5 | 0.5 | 0.5 | 0.5 | 0.5 | 0.5 |
| | | Photopolymerization | Omn 127D | Omn 127D | Omn 127D | Omn 127D | Omn 127D | Omn 127D |
| | | initiator | | | | | | |
| | | Number of parts | 3 | 3 | 3 | 3 | 3 | 3 |
| | | Additive 1 | — | — | — | — | — | PPG |
| | | Number of parts | — | — | — | — | — | 3 |
| | | Additive 2 | — | — | — | — | — | 3000TL |
| | | Number of parts | — | — | — | — | — | 5 |
| | Base material | | *PP | *PP | *PP | PE | PET | *PP |
| Evaluation | Pressure- | Modulus of | 0.948 | 0.282 | 0.468 | 0.366 | 0.366 | 0.197 |
| | sensitive | elasticity before | | | | | | |
| | adhesive layer | UV (MPa) | | | | | | |
| | SS | | | | | | | |
| | With respect to | Before UV | 2.443 | 3.372 | 3.078 | 2.548 | 2.944 | 3.12 |
| | Si (90° peel) | After UV (460 mJ) | 0.058 | 0.037 | 0.048 | 0.048 | 0.075 | 0.02 |
| | Anchoring force | Before UV | 6.2 | 6.7 | 5.1 | 6.8 | 7.1 | 5.7 |
| | (using BT-315) | After UV (460 mJ) | 3.1 | 4.2 | 5.4 | 5.6 | 5.4 | 5.1 |

| | | | | | | |
|---|---|---|---|---|---|---|
| Breaking mode at anchoring force | Interfacial | Interfacial | Interfacial | Interfacial | Interfacial | Interfacial |
| after UV | | | | | | |
| Embedding of base material | o | o | o | o | o | o |
| | (good) | (good) | (good) | (good) | (good) | (good) |
| Embedding of adherend | o | o | o | o | o | o |
| | (good) | (good) | (good) | (good) | (good) | (good) |
| Pick-up (adhesive residue) | o | o | o | o | o | o |
| | (good) | (good) | (good) | (good) | (good) | (good) |

*Three-layer structure of PP/EVA/PP

TABLE 2

| | | | Comp | Comp. | Comp. | Comp. | Comp. | Comp. |
|---|---|---|---|---|---|---|---|---|
| | | | Example 1 | Example 2 | Example 3 | Example 4 | Example 5 | Example 6 |
| Pressure- | Pressure- | Polymer | Polymer 1 | Polymer 1 | Polymer 1 | Polymer 1 | Polymer 1 | Polymer 2 |
| sensitive | sensitive | Number of parts | 100 | 100 | 100 | 100 | 100 | 100 |
| adhesive | adhesive | Cross-linking | C/L | C/L | C/L | C/L | C/L | TAKENATE |
| sheet | layer | agent | | | | | | |
| | | Number of parts | 0.5 | 0.5 | 0.5 | 0.5 | 0.5 | 0.01 |
| | | Surfactant | None | NS230 | TH330K | S-40TD | S-4DV | RL-210 |
| | | ( Phosphoric | | | | | | |
| | | acid ester) | | | | | | |
| | | Number of parts | 0 | 0.3 | 0.3 | 0.3 | 0.3 | 0.5 |
| | | Photopolymerization | Omn 127D | Omn 127D | Omn 127D | Omn 127D | Omn 127D | Omn 127D |
| | | initiator | | | | | | |
| | | Number of parts | 3 | 3 | 3 | 3 | 3 | 3 |
| | | Additive 1 | — | — | — | — | — | — |
| | | Number of parts | — | — | — | — | — | — |
| | | Additive 2 | — | — | — | — | — | — |
| | | Number of parts | — | — | — | — | — | — |
| | Base material | | *PP | *PP | *PP | *PP | *PP | *PP |
| Evaluation | Pressure- | Modulus of | 0.345 | 0.247 | 0.260 | 0.232 | 0.256 | 0.267 |
| | sensitive | elasticity | | | | | | |
| | adhesive | before UV (MPa) | | | | | | |
| | layer SS | | | | | | | |
| | With | Before UV | 3.376 | 2.872 | 2.854 | 2.605 | 1.850 | 3.088 |
| | respect to | After UV (460 | 0.032 | 0.030 | 0.025 | 0.029 | 0.021 | 0.045 |
| | Si (90° | mJ) | | | | | | |
| | peel) | | | | | | | |
| | Anchoring | Before UV | 6.7 | 6.7 | 6.7 | 7.0 | 6.7 | 8.0 |
| | force | After UV (460 | 0.2 | 0.15 | 0.2 | 0.2 | 0.35 | 0.5 |
| | (using BT- | mJ) | | | | | | |
| | 315) | | | | | | | |
| | Breaking mode at anchoring | | Anchoring | Anchoring | Anchoring | Anchoring | Anchoring | Anchoring |
| | force after UV | | | | | | | |
| | Embedding of base material | | o | o | o | o | o | o |
| | | | (good) | (good) | (good) | (good) | (good) | (good) |
| | Embedding of adherend | | o | o | o | o | o | o |
| | | | (good) | (good) | (good) | (good) | (good) | (good) |
| | Pick-up (adhesive residue) | | x | x | x | x | x | x |
| | | | (not good) | (not good) | (not good) | (not good) | (not good) | (not good) |
| | | | Comp. | Comp. | Comp. | Comp. | Comp. | Comp. |
| | | | Example 7 | Example 8 | Example 9 | Example 10 | Example 11 | Example 12 |
| Pressure- | Pressure- | Polymer | Polymer 2 | Polymer 2 | Polymer 2 | Polymer 2 | Polymer 2 | Polymer 1 |
| sensitive | sensitive | Number of parts | 100 | 100 | 100 | 100 | 100 | 100 |
| adhesive | adhesive | Cross-linking | TAKENATE | TAKENATE | TAKENATE | TAKENATE | TAKENATE | TAKENATE |
| sheet | layer | agent | | | | | | |
| | | Number of parts | 0.5 | 3 | 5 | 0.5 | 0.5 | 0.5 |
| | | Surfactant | None | None | None | None | None | None |
| | | ( Phosphoric | | | | | | |
| | | acid ester) | | | | | | |
| | | Number of parts | 0 | 0 | 0 | 0 | 0 | 0 |
| | | Photopolymerization | Omn 127D | Omn 127D | Omn 127D | Omn 127D | Omn 127D | Omn 127D |
| | | initiator | | | | | | |
| | | Number of parts | 3 | 3 | 3 | 3 | 3 | 3 |
| | | Additive 1 | — | — | — | - | - | PPG |
| | | Number of parts | — | — | — | - | - | 3 |
| | | Additive 2 | — | — | — | - | - | 3000TL |
| | | Number of parts | — | — | — | - | - | 5 |
| | Base material | | *PP | *PP | *PP | PE | PET | *PP |
| Evaluation | Pressure- | Modulus of | 0.666 | 1.388 | 1.949 | 0.666 | 0.666 | 0.336 |
| | sensitive | elasticity | | | | | | |
| | adhesive | before UV (MPa) | | | | | | |
| | layer SS | | | | | | | |
| | With | Before UV | 4.685 | 4.225 | 4.002 | 4.782 | 4.372 | 3.88 |
| | respect to | After UV (460 | 0.062 | 0.058 | 0.055 | 0.066 | 0.066 | 0.042 |
| | Si (90° | mJ) | | | | | | |
| | peel) | | | | | | | |
| | Anchoring | Before UV | 10.0 | 9.2 | 9.8 | 8.9 | 8.2 | 6.3 |
| | force | After UV (460 | 0.7 | 3.2 | 4 | 0.2 | 0.15 | 0.2 |
| | (using BT- | mJ) | | | | | | |
| | 315) | | | | | | | |

| | | | | | | |
|---|---|---|---|---|---|---|
| Breaking mode at anchoring | Anchoring | Interfacial | Interfacial | Anchoring | Anchoring | Anchoring |
| force after UV | | | | | | |
| Embedding of base material | o | o | x | o | o | o |
| | (good) | (not good) | (not good) | (good) | (good) | (good) |
| Embedding of adherend | o | x | x | o | o | o |
| | (good) | (not good) | (not good) | (good) | (good) | (good) |
| Pick-up (adhesive residue) | x | o | o | x | x | x |
| | (not good) | (good) | (good) | (not good) | (not good) | (not good) |

*Three-layer structure of PP/EVA/PP

The pressure-sensitive adhesive sheet for semiconductor processing of the present disclosure has excellent followability to unevenness and an excellent anchoring property. Accordingly, the pressure-sensitive adhesive sheet can be suitably used in a processing process for a semiconductor having unevenness on its surface. In addition, reduction of an anchoring force in a solvent is suppressed, and hence the pressure-sensitive adhesive sheet can be suitably used in a semiconductor production process including a solvent washing step.

According to at least one embodiment of the present disclosure, the pressure-sensitive adhesive sheet for semiconductor processing having excellent followability to unevenness and an excellent anchoring property can be provided. In the pressure-sensitive adhesive sheet for semiconductor processing according to at least one embodiment of the present disclosure, the anchoring property between the base material and the pressure-sensitive adhesive layer can be maintained even after the pressure-sensitive adhesive layer is cured through UV irradiation. Accordingly, when the pressure-sensitive adhesive sheet for semiconductor processing after the UV irradiation is peeled, an adhesive residue on an adherend (e.g., a semiconductor wafer) can be prevented. In addition, even when the pressure-sensitive adhesive sheet is used in a semiconductor processing process including a solvent washing step, reduction of an anchoring force of the pressure-sensitive adhesive layer to the base material can be suppressed.

What is claimed is:

1. A pressure-sensitive adhesive sheet for semiconductor processing, comprising:
a pressure-sensitive adhesive layer formed of an ultra-violet (UV)-curable pressure-sensitive adhesive; and
a base material,
wherein the UV-curable pressure-sensitive adhesive contains a base polymer, a photopolymerization initiator, and a phosphoric acid ester-based surfactant.

2. The pressure-sensitive adhesive sheet for semiconductor processing according to claim 1, wherein the phosphoric acid ester-based surfactant has a content of 0.03 part by weight or more with respect to 100 parts by weight of the base polymer.

3. The pressure-sensitive adhesive sheet for semiconductor processing according to claim 1, wherein the pressure-sensitive adhesive layer has an anchoring force after UV curing of 1 N/20 mm or more.

4. The pressure-sensitive adhesive sheet for semiconductor processing according to claim 1,
wherein the UV-curable pressure-sensitive adhesive further contains a cross-linking agent, and
wherein the cross-linking agent has a content of 1 part by weight or less with respect to 100 parts by weight of the base polymer.

5. The pressure-sensitive adhesive sheet for semiconductor processing according to claim 4, wherein the cross-linking agent is an isocyanate-based cross-linking agent.

6. The pressure-sensitive adhesive sheet for semiconductor processing according to claim 1, wherein the base polymer is a polymer having a carbon-carbon double bond.

7. The pressure-sensitive adhesive sheet for semiconductor processing according to claim 1, wherein the base material contains a polyolefin-based resin.

8. The pressure-sensitive adhesive sheet for semiconductor processing according to claim 1, wherein the pressure-sensitive adhesive sheet for semiconductor processing is used in a semiconductor processing process including a solvent washing step.
